(19) United States
(12) Patent Application Publication
(10) Pub. No.: US 2004/0145279 A1
(43) Pub. Date: Jul. 29, 2004

(54) High-efficiency piezoelectric transformer and ballast

(76) Inventors: Hee Jin Kim, Choongcheong buk-do (KR); Dong Soo Paik, Seoul (KR)

Correspondence Address: Andrew M Riddles, Morgan & Finnegan, 345 Park Avenue, New York, NY, 10154, US

(21) Appl. No.: 10/472,108

(22) PCT Filed: Mar. 14, 2001
(86) PCT No.: PCT/KR01/00398

(51) Int. Cl. H01L 41/107

(52) U.S. Cl. 310/359

(57) ABSTRACT

The present invention relates to piezoelectric transformer and ballast using the same transformer utilizing piezoelectric and inverse piezoelectric effects, more specifically to high-efficiency piezoelectric transformer and ballast using the same transformer which can obtain a large output current using novel electrode structure and polarization direction. According to the present invention, a piezoelectric transformer comprises a piezoelectric ceramic body having a planar form of circle or ring, first and second electrodes formed adjacent to the top and bottom surface of the piezoelectric ceramic body, the first and second electrodes having the same planar structure as the body and divided to N parts spaced a constant distance each other and the first and second electrodes being plane symmetry with the body. The whole area of the body is polarized as the same direction and an input voltage is applied to N1 of the first electrodes, a negative voltage is applied to N1 of the first electrodes, a negative voltage is applied to all of the second electrodes and a output voltage is obtained through the rest N-N1 of the first electrodes. The second electrodes may be formed as one body having same planar structure as the piezoelectric ceramic body. Then, it is possible that an input voltage is applied to the second electrode, a negative voltage is applied to N1 of the first electrodes and a output voltage is obtained through the rest N-N1 of the first electrodes Divided electrodes can be coupled serial and/or parallel.

### BACKGROUND OF THE INVENTION

1. Field of the Invention

The present invention relates generally to piezoelectric transformer which amplifies voltage using piezoelectric effect and converse piezoelectric effect of piezoelectric material, in particular, to a piezoelectric transformer in which improvements are made in configuration and arrangement of the electrodes for high output and high efficiency. The present invention further relates to high-efficiency piezoelectric ballast which can light up discharge lamp(s) at commercially supplied power lines (110V/220V) using such high-output piezoelectric transformer.

2. Description of the Prior Art

A practical study about piezoelectric transformer has been conducted for the first time by C. E. Rosen, et al. from the General Electric Company in the U.S.A. as early as 1957. However, the piezoelectric material used then was barium titanate, which had a voltage step-up range of about 50 to 60 times at no-load, so that practicability thereof was poor. New piezoelectric material using Pb(Zr,Ti)O₃ as its main component has been discovered and hence step-up of higher voltages has been made feasible, leading to the full-scale researches for practical use.

Comparing the piezoelectric transformer with a conventional wound transformer, the piezoelectric transformer uses piezoelectric effect and converse piezoelectric effect, whereas the wound transformer employs a voltage step-up method using electro-magnetic induction. Therefore, the piezoelectric transformer has less problem with electro-magnetic noise. Further, the voltage step-up ratio of the piezoelectric transformer is determined by the characteristics of the materials, configuration of electrodes, dimension, load characteristics, etc., whereas that of a wound transformer is determined by the winding factor. In particular, as to the output power, in order to change the secondary part to have the feature of high voltage and low current, a wound transformer has to increase the winding factor, which inevitably causes increase of leakage component, whereas the piezoelectric transformer using piezoelectric body can realize a 90% efficiency. Accordingly, if the piezoelectric transformer is utilized in a ballast, it can save more energy than the electronic ballasts currently employed in the conventional discharge lamps. Such a transformer capable of obtaining high voltage and low current at secondary part has a better impedance matching at high impedance load resulting in higher efficiency, whereby the load characteristic can be made comparable to increase the efficiency of energy transformation.

The piezoelectric transformer with the feature of high voltage and low current has so far been successfully realized and the piezoelectric inverter for backlight of a notebook computer, to which this transformer applies, is now in common use. In the meantime, notebook computers continue to be smaller-sized and lighter-weighed. In this regard, the conventional wound transformer is not only limited in size and weight due to the insulation and high voltage breakdown, but also its efficiency is degraded due to the winding loss such as core loss, whereas the piezoelectric transformer which is capable of overcoming aforementioned defects, provides good impedance matching of the piezoelectric transformer with the notebook LCD backlight. Accordingly, the piezoelectric transformer has been in application for this purpose and some ignition devices using piezoelectric transformer are supplied. Researches for high output of 1^{st} mode Rosen type, 3^{rd} mode Rosen type, etc. are actively carried out recently, and studies in lamination methods for parallel operation are in progress, too.

However, the known conventional piezoelectric transformers show their limitations in obtaining output of high current. In particular, since the Rosen type with planar structure has a drive section and an output section of which the poling directions are perpendicular to each other, the stress convergence at boundary is highly intensive; since the high electric field (3 kV/mm) is applied at poling process of the output section, a polarizing can hardly occur; and since the electrode area of the output terminal is so small that high current can hardly be obtained; whereby nothing can be obtained but output of high voltage and low current, which is not suitable to light a lamp with large current therein such as fluorescent lamp. In order to solve these problems, physically separate multiple transformers should be manufactured to be driven in parallel. However, here, the resonant frequencies would hardly be equalized due to difficulty in regulating the exact dimensions of the transformers, and degradation of the output characteristics would not be avoided due to defects in the poling process.

### SUMMARY OF THE INVENTION

The present invention, conceived to solve the above problems, aims to provide a piezoelectric transformer which is capable of increasing the output current in contrast to the afore-mentioned low-output piezoelectric transformers.

A further objective of the present invention is to provide a piezoelectric transformer which has a novel configuration of electrodes and a novel arrangement of poling directions.

It is another objective of the present invention, to provide a high-efficiency piezoelectric ballast using the above piezoelectric transformer, which can light, in a stable manner at home input voltage (220V/110V) without use of a wound transformer in the drive circuit, a general fluorescent lamp of high voltage and of large current, which cannot be operated by conventional piezoelectric transformers.

In order to achieve the above objectives, the present invention provides a piezoelectric transformer which comprises a planar disc-type or ring-type body made of piezoelectric material; and the first and the second electrodes, both of which having the structure that the same planar structure as the body is divided into N sections with predetermined spacing therebetween in a manner that the arrangement of the first and the second electrodes is symmetrical with respect to the plane of the body, are formed adjacent to the upper and the lower surfaces of the body, respectively. Here, the body is polarized throughout in an equal poling direction; N1 sections of the first electrode (N1=positive integer, N1<N) are supplied with the input voltage; the second electrode is supplied with common negative potential; and the output voltage is taken from N-N1 sections of the first electrode.

Another piezoelectric transformer according to the present invention comprises a planar disc-type or ring-type body made of piezoelectric material; the first electrode, having the structure that the same planar structure as the body is divided into N sections with predetermined spacing therebetween, is formed adjacent to one of the upper and the lower surfaces of the body; and the second electrode, having the same planar structure as the body, is monolithically formed adjacent to the surface opposite to the surface formed adjacent to the first electrode. Here, the body is polarized throughout in an equal poling direction; N1 sections of the first electrode (N1=positive integer, N1<N) are supplied with the input voltage; the second electrode is supplied with negative potential; and the output voltage is taken from N-N1 sections of the first electrode.

Here, it is also possible that the input voltage is applied to the second electrode; the negative potential is applied to N1 sections (N1=positive integer, N1<N) of the first electrode; and the output voltage is taken from N-N1 sections of the first electrode.

In the piezoelectric transformer according to the present invention, the body is poled in an axial direction (thus perpendicular to the plane of the body); N1 electrodes to which the input voltage is applied are connected in parallel or in series or in combination of parallel and series; and the connected N1 electrodes are arranged physically to be contiguous to each other or are arranged to alternate with the rest N-N1 of the electrodes that are not supplied with the input voltage.

Further, since N-N1 electrodes from which the output voltage is taken can each be independently connected in parallel to no more than N-N1 loads, no more than N-N1 multiple outputs can be obtained by using a single piezoelectric device.

A high-efficiency ballast for fluorescent lamp can be manufactured using such piezoelectric transformer and the corresponding drive circuit. A piezoelectric ballast for fluorescent lamp according to the present invention comprises an a.c. power supply including an overcurrent protection device, overvoltage protection member and an EMI prevention circuit; a power factor improving circuit connected to the a.c. power supply; a rectifier connected to the power factor improving circuit; a pulse generator receiving the input voltage from the a.c. power supply; a switching frequency setting circuit for setting switching frequency of the pulse generator; a resonant circuit comprising a drive transformer that transforms the output from the pulse generator, two field-effect transistors that are connected to the drive transformer for switching the output a.c. voltage from the rectifier, an inductor connected to the two field-effect transistors, a piezoelectric transformer connected to the inductor in series, and a fluorescent lamp; and a reset circuit which is connected to the pulse generator for resetting the pulse generator in the event of overload or no-load, the piezoelectric transformer included in the resonant circuit having the same configuration as described above.

Here, the reset circuit comprises a secondary winding that is formed facing the inductor for detecting anomalous current in the fluorescent lamp at overload or no-load; a zener diode connected to the secondary winding for detecting anomalous voltage; and a SCR (Silicon-Controlled Rectifier) that is operated by a signal from the zener diode.

In another piezoelectric ballast for fluorescent lamp according to the present invention, the above resonant circuit comprises at least two fluorescent lamps that are connected in series and the ballast further comprises a series no-load circuit which, connected to each of the above series-connected two fluorescent lamps, allows the current to flow only in the other lamp that is not extinguished while at the same time cutting off the circuit for the extinguished lamp, if one of the lamps is turned off with no-load.

In such a way, the piezoelectric ballast for fluorescent lamp according to the present invention can improve its productivity due to the equal poling direction and can minimize the fatigue-fracture behavior caused by anisotropy of the poling.

### BRIEF DESCRIPTION OF THE DRAWINGS

FIG. 1 shows the configuration of the electrodes (uniform dividing into 4 divisions) of the disc-type piezoelectric transformer according to the first embodiment of the present invention, wherein (a) indicates the upper surface and (b) and (c) indicate the lower surface.

FIG. 2 shows the configuration of the electrodes of the disc-type piezoelectric transformer according to the second and third embodiments of the present invention, wherein (a) illustrates the uniformly-divided six divisional electrodes and (b) illustrates the uniformly-divided eight divisional electrodes.

FIG. 3 shows the configuration of the electrodes (uniform dividing into 4 divisions) of the ring-type piezoelectric transformer according to the third embodiment of the present invention, wherein (a) indicates the upper surface and (b) and (c) indicate the lower surface.

FIG. 4 shows the configuration of the electrodes (multiform dividing into 2 divisions) of the disc-type piezoelectric transformer according to the fourth embodiment of the present invention, wherein (a) indicates the upper surface and (b) and (c) indicate the lower surface.

FIG. 5 shows the configuration of the electrodes (multiform dividing into 4 divisions) of the disc-type piezoelectric transformer according to the fifth embodiment of the present invention, wherein (a) indicates the upper surface and (b) and (c) indicate the lower surface.

FIG. 6 shows the configuration of the electrodes (asymmetric dividing into 2 divisions) of the ring-type piezoelectric transformer according to the sixth embodiment of the present invention, wherein (a) indicates the upper surface and (b) and (c) indicate the lower surface.

FIG. 7 shows the poling direction of the disc-type piezoelectric transformer according to the first embodiment of the present invention, wherein the upper electrode serves as (+) terminal while the lower electrode serves as (−) terminal.

FIG. 8 shows the configuration of the electrodes of the disc-type piezoelectric transformer according to the seventh embodiment of the present invention, wherein (a) indicates the upper surface and (b) and (c) indicate the lower surface.

FIG. 9 illustrates the circuit diagram for parallel driving of the disc-type piezoelectric transformer according to the first embodiment of the present invention.

FIG. 10 illustrates the circuit diagram for series driving of the disc-type piezoelectric transformer according to the first embodiment of the present invention

In FIG. 11 (a) represents the planar vibration mode at resonant frequency of the piezoelectric transformer with uniform-divided eight electrodes according to the third embodiment of the present invention and (b) represents the planar vibration mode of the disc-type oscillator having a monolithic upper electrode and a monolithic lower electrode.

FIG. 12 shows the circuit diagram of the piezoelectric transformer for fluorescent lamp which is electroded with uniformly-divided eight divisional electrodes according to the third embodiment of the present invention, wherein (a) indicates that the divisional electrodes serve as the input section (drive section) and (b) indicates that the monolithic electrode serves as the drive section.

FIG. 13 illustrates the drive circuit of a ballast for lighting a 10-64 W discharge lamp using the piezoelectric transformer according to the present invention.

FIG. 14 shows the waveforms of tubular voltage and of tubular current of a fluorescent lamp ignited by the piezoelectric ballast according to the present invention.

FIG. 15 illustrates the drive circuit of the piezoelectric ballast for series-connected two lamps according to the present invention.

### DETAILED DESCRIPTION OF THE OF THE PREFERRED EMBODIMENTS

Below, the preferred embodiments of the present invention are described in detail making reference to the accompanying drawings.

FIG. 1 shows the configuration of the electrodes (uniform dividing into 4 divisions) of the disc-type piezoelectric transformer according to the first embodiment of the present invention, wherein (a) indicates the upper surface and (b) and (c) indicate the lower surface.

As FIG. 1(a) illustrates, the upper electrodes 1, 2, 3, and 4, located on the upper surface of the disc-type piezoelectric transformer, are formed to have a structure that the disc is divided into four equal divisions, each electrode being spaced with a predetermined interval of g. The lower electrodes 1′, 2′, 3′, and 4′ are formed opposite to the upper electrodes 1, 2, 3, and 4 respectively in a manner symmetric to the plane of the body, see FIG. 1(b), or the lower electrode can also be formed in a monolithic manner, see FIG. 1(c).

A description of an example of the connection method for the drive section of the piezoelectric transformer according to the first embodiment of the present invention having electrodes configuration as shown in FIG. 1 is given in the following.

In case of a parallel connection, the physically adjacent electrodes 1 and 4 among the upper electrodes are connected for serving as (+) terminal and the symmetrically opposite lower electrodes 1′ and 4′ are connected for serving as (−) terminal. Or, it is also possible that the upper electrodes 1 and 3 diagonally facing to each other are connected for serving as (+) terminal and the symmetrically opposite lower electrodes 1′and 3′ are connected for serving as (−) terminal.

In case of a series connection, one of the upper electrodes and one of the lower electrodes 1, 1′ which are symmetrically arranged with respect to the piezoelectric ceramics located therebetween are rendered (+) terminal and the respective adjacent electrodes 2, 2′ are rendered (−) terminal. Or, it is also possible that the (+) terminal is composed of one upper electrode and one lower electrode 1, 1′ which are symmetrically arranged with respect to the piezoelectric ceramics located therebetween and the (−) terminal is composed of electrodes 3 and 3′ diagonally facing to electrodes 1 and 1′, respectively.

Meanwhile, the output terminal is operated in parallel regardless of how the drive section is connected and the (−) terminal of the drive section and the (−) terminal of the output section are connected to be used as (−) terminal of the load and other electrodes excluding those of the drive section are connected in parallel to be used as (+) terminal of the load.

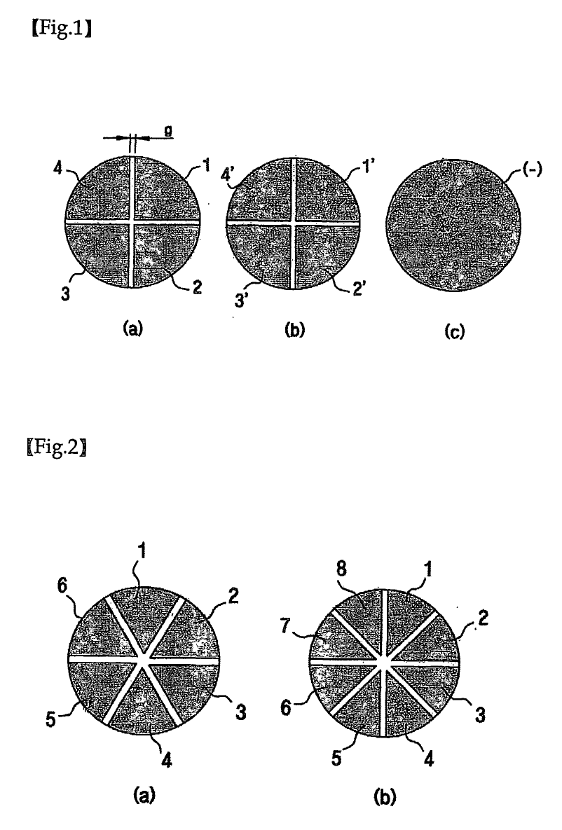

FIG. 2 shows the configuration of the electrodes of the disc-type piezoelectric transformer according to the second and the third embodiments of the present invention, wherein (a) illustrates the configuration of uniformly-divided six divisional electrodes and (b) illustrates the configuration of uniformly-divided eight divisional electrodes. Similar to the first embodiment, the upper electrodes on the upper surface are formed by dividing the disc into six equal divisions (FIG. 2(a): 1˜6) or eight equal divisions (FIG. 2(b): 1˜8) and the lower electrode is so formed that the upper and the lower electrodes are symmetrical to each other with respect to the plane of the body, or the same can be formed in a monolithic fashion.

In case of uniform dividing into six divisions as in the second embodiment, in order to equalize the number of electrodes of the drive section and of the output section, the adjacent three electrodes (for example, 1˜3) are connected in parallel or the alternate-positioned three electrodes (for example, 1, 3, 5) are connected in parallel. Or, the electrodes of the foregoing examples are connected in series.

However, it is not indispensably required for the drive section and the output section to have the same number of electrodes. For example, in case of parallel connection, electrodes 1 and 2 can be rendered the drive section (primary part) and electrodes 3 through 6 can be rendered the output section (secondary part). In this manner, the number of electrodes of the drive section and that of the output section can be varied.

In case of uniform dividing into eight divisions as in the third embodiment, the drive section can be formed \mathring{1} by parallel connection of the adjacent electrodes such as electrodes 1, 2, 3, 4; \mathring{2} by parallel connection of the alternate electrodes such as electrodes 1, 3, 5, 7; \mathring{3} by series connection of the adjacent electrodes such as electrodes 1, 2, 3, 4; \mathring{4} by series connection of the alternate electrodes such as electrodes 1, 3, 5, 7; or \mathring{5} by parallel connection of the series-connected two pairs 1, 2 (or 1, 3) and 3, 4 (or 5, 7) after series connections of electrodes 1, 2 (or 1, 3) and of electrodes 3, 4 (or 5, 7).

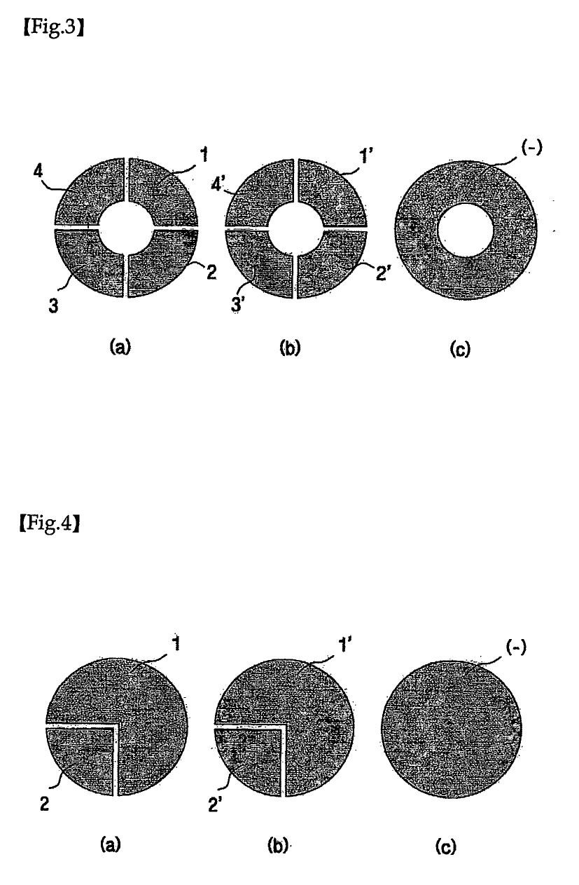

FIG. 3 shows the configuration of the electrodes (uniform dividing into 4 divisions) of the ring-type piezoelectric transformer according to the third embodiment of the present invention, wherein (a) indicates the upper surface and (b) and (c) indicate the lower surface.

In FIG. 3(a), the upper electrodes 1, 2, 3, 4, located on the upper surface of the ring-type piezoelectric transformer, are formed to have a structure that the annular shaped body is divided into four uniform divisions, each electrode having a predetermined spacing. The lower electrodes 1′, 2′, 3′, 4′ are formed, see FIG. 3(b), in a manner that the upper and the lower electrodes are symmetrical with respect to the plane of the disc, or the lower electrode can also be formed in a monolithic manner, see FIG. 3(c).

FIG. 4 shows the configuration of the electrodes (multiform dividing into 2 divisions) of the disc-type piezoelectric transformer according to the fourth embodiment of the present invention, wherein (a) indicates the upper surface and (b) and (c) indicate the lower surface.

The fourth embodiment differs from the first through third embodiments in that the electrodes of the piezoelectric transformer have a structure formed by a multiform dividing. Namely, as illustrated in FIG. 4, the upper electrode is composed of electrode 1 which occupies three-fourth of the disc area and electrode 2 which occupies the rest of the area, i.e., one-fourth of the disc area. The lower electrode is formed in a manner that the arrangement of the upper and the lower electrodes is symmetrical with respect to the plane of the body as described in the foregoing embodiments (FIG. 4(b): 1′, 2′), or it can also be formed in a monolithic fashion (FIG. 4c: (−)).

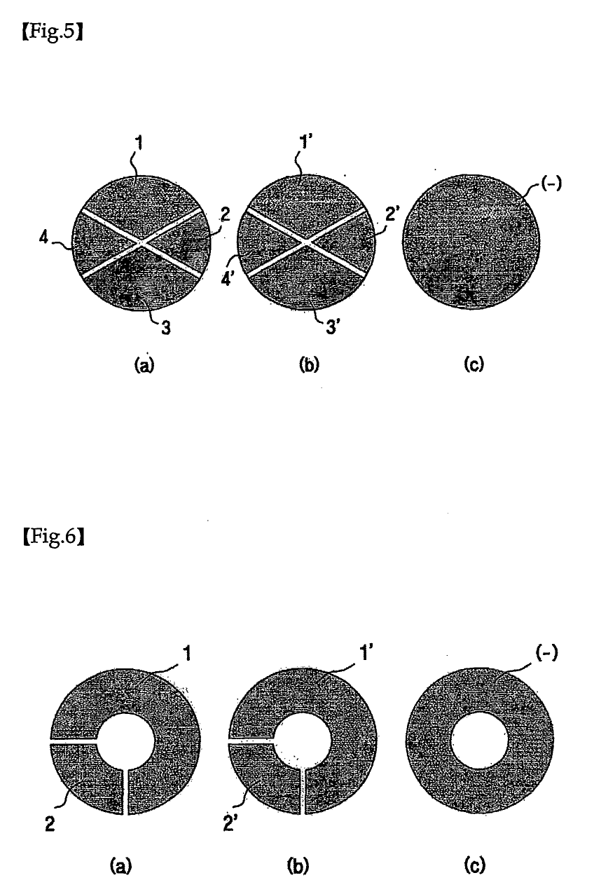

FIG. 5 shows the configuration of the electrodes (multiform dividing into 4 divisions) of the disc-type piezoelectric transformer according to the fifth embodiment of the present invention, wherein (a) indicates the upper surface and (b) and (c) indicate the lower surface.

The fifth embodiment differs from the first embodiment in that the upper electrodes 1, 2, 3, and 4 are formed by dividing the disc into four multiform divisions. The lower electrodes 1′, 2′, 3′, and 4′ are formed opposite to the upper electrodes 1, 2, 3, and 4, respectively (i.e., the overall configuration of the electrodes is symmetrical) with respect to the plane of the body, see FIG. 5(b). Or, the lower electrode can be formed in a monolithic manner, see FIG. 5(c).

FIG. 6 shows the configuration of the electrodes (asymmetric dividing into 2 divisions) of the ring-type piezoelectric transformer according to the sixth embodiment of the present invention, wherein (a) indicates the upper surface and (b) and (c) indicate the lower surface.

As shown in FIG. 6, the sixth embodiment provides the multiform-divided electrodes as in the fifth embodiment, which are formed by dividing the annularly-shaped plate as in the fourth embodiment in a non-uniform manner.

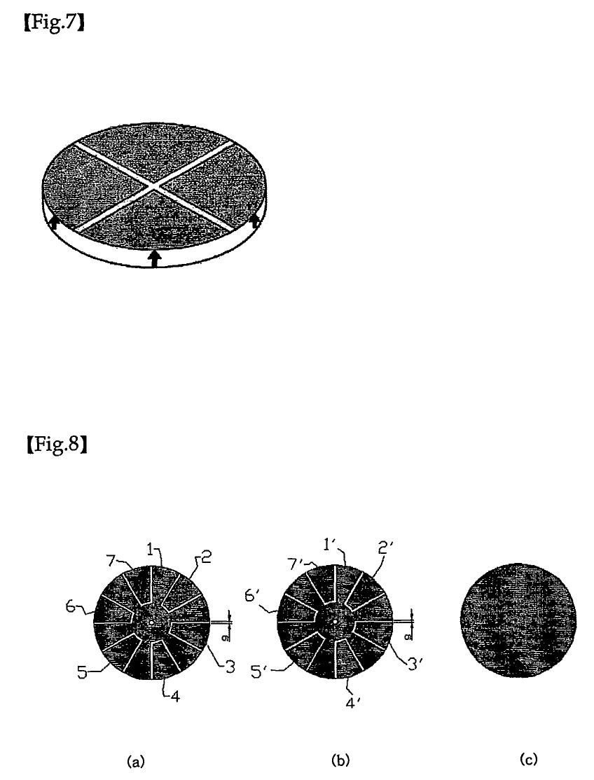

FIG. 7 illustrates the poling direction of the disc-type piezoelectric transformer according to the first embodiment of the present invention. As shown in FIG. 7, in the first embodiment, the upper electrode serves as (+) terminal and the lower electrode serves as (−) terminal so that the entire area of the piezoelectric transformer has an equal poling direction. In such a way, the fatigue-fracture behavior which is caused by anisotropic poling direction at each section of the piezoelectric transformer (drive section and output section) can be minimized.

That the poling direction is made equal throughout the piezoelectric transformer applies also to other embodiments of the present invention.

FIG. 8 shows the configuration of the electrodes of the disc-type piezoelectric transformer according to the seventh embodiment of the present invention, wherein (a) indicates the upper surface and (b) and (c) indicate the lower surface.

As shown in FIG. 8(a), the upper electrode is composed of the sunbeam-like radial-shaped electrode 1 and a plurality of electrodes 2˜7 which are arranged between the sunbeam-like shapes of electrode 1, and the lower electrode is composed of 1′˜8′ which are opposite to the upper electrodes 1-8 respectively, in symmetry with respect to the plane of the body, see FIG. 8(b). Or, the lower electrode can also be formed in a monolithic manner, see FIG. 8(c). Here, the sunbeam-like radial-shaped electrode 1 serves as the drive section, the other electrodes 2, 3, 4, 5, 6, and 7 serve as the output section, and the lower electrodes 1′, 2′, 3′, 4′, 5′, 6′, and 7′ are connected along to be further connected to (−) terminal in case the lower electrode is formed as in FIG. 8(b). In case the lower electrode is formed as in FIG. 8(c), the monolithic lower electrode is directly connected to (−) terminal. Here, the output sections 2˜7 can each be connected to a load or all the output sections can be connected to one load at the same time for parallel driving.

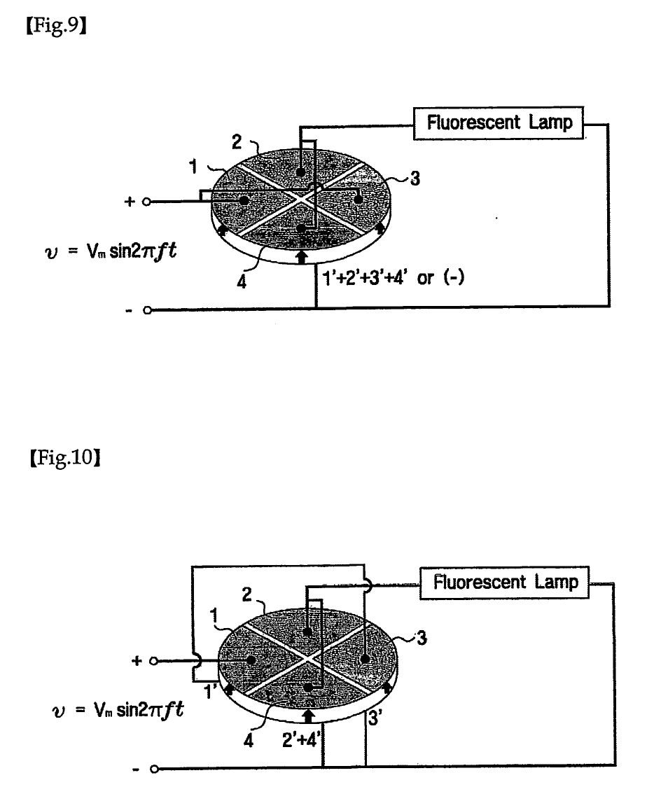

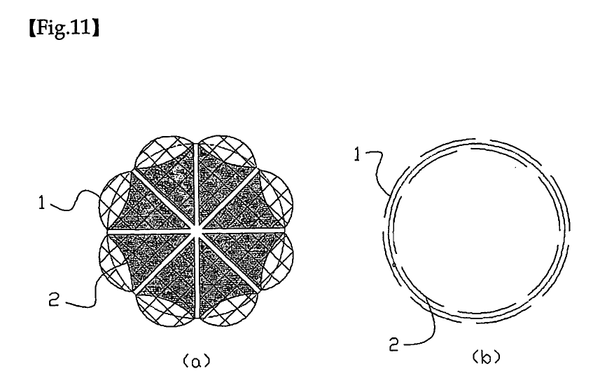

An example of the method for operating the piezoelectric transformer according to the present invention is described in detail below making reference to the drawings. FIG. 9 illustrates the circuit diagram for parallel driving of the disc-type piezoelectric transformer according to the first embodiment of the present invention while FIG. 10 illustrates that for series driving of the disc-type piezoelectric transformer according to the first embodiment of the present invention

The piezoelectric transformer comprises a disc-type piezoelectric element which is 2 mm in thickness and 34.7 mm in diameter with uniformly-divided four sectorial electrodes arranged respectively on the upper surface and on the lower surface of the piezoelectric element in an equal poling direction as in the first embodiment. In case of parallel driving, electrodes 1, 3 for the drive section and electrodes 2, 4 for the output section are set to face each other, see FIG. 9.

In case of series driving, see FIG. 10, electrode 1 is rendered (+) terminal and electrodes 3′ is rendered (−) terminal after electrodes 1′ and 3 are connected. The output sections are electrode 2 and electrode 4.

The resonant frequencies calculated for the parallel-driven circuit as in FIG. 1 are 49.4 kHz in λ/2 mode, 74.1 kHz in 3λ/2 mode, and 98.8 kHz in λ mode. The substantial frequencies while driving were each within the range of ±1 kHz from these calculated frequencies.

Further, the output characteristics as per vibration mode in the case of operating the drive section of the piezoelectric transformer in parallel at 100 kΩ of load resistance are shown in Table 1. As shown in Table 1, the maximum output is obtained in 3λ/2 mode. This shows a tendency different from that of the primary Rosen type piezoelectric transformer which has the maximum output in λ mode. It is considered that the difference in the output characteristics is due to the difference of the vibration pattern.

TABLE 1
Output characteristics according to vibration mode

| Vibration Mode | Output Ratio |
|---|---|
| λ/2 | 50 |
| 3λ/2 | 130 |
| λ | 60 |

FIG. 11 (a) represents the planar vibration mode at resonant frequency of the piezoelectric transformer with uniformly-divided eight divisional electrodes according to the third embodiment of the present invention and (b) represents the planar vibration mode of the disc-type oscillator having a monolithic upper electrode and a monolithic lower electrode.

To be specific, when the contraction is made in axial direction at resonant frequency, the expansion is made in planar direction on the basis of the boundary of each electrode, see FIG. 11(a)-1, and when the expansion is made in axial direction, the contraction is made in planar direction, see FIG. 11(a)-2.

FIG. 11(b) illustrates the planar vibration mode of the oscillator with the monolithic electrodes.

To compare FIG. 11(a) with FIG. 11(b), the vibration-generating spots are 8 spots in FIG. 11(a), which is 8 times as many as in FIG. 11(b). Accordingly, it can be known that the vibration displacement density of the piezoelectric transformer pursuant to the present invention will be greatly increased. Owing to such increase in vibration displacement density, high-output can be obtained despite the equal poling direction, for output from the output section is proportional to the displacement density.

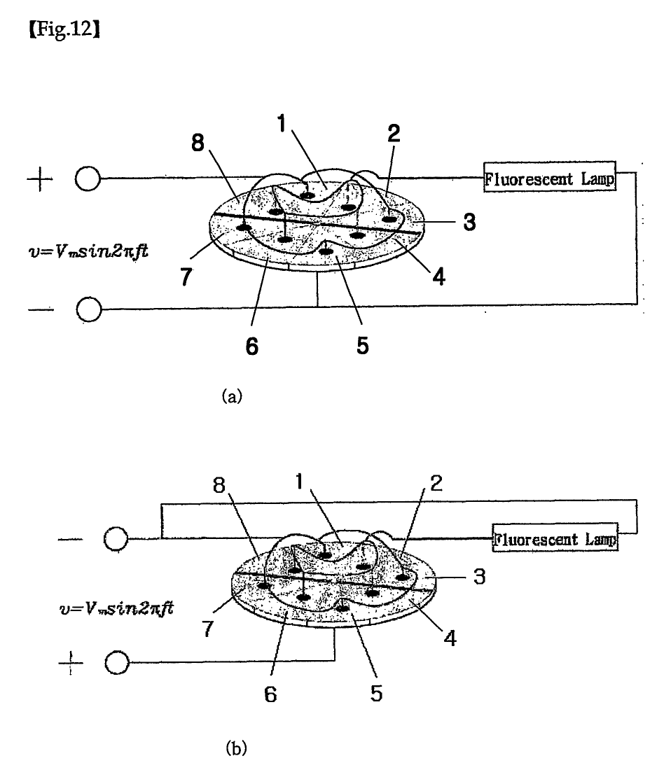

FIG. 12 is the circuit diagram of the piezoelectric transformer for fluorescent lamp which has uniformly-divided eight divisional electrodes according to the third embodiment of the present invention, wherein (a) shows a case where the divisional electrodes serve as the input section (drive section) and (b) shows a case where the monolithic electrode serves as the drive section. The piezoelectric transformer as in FIG. 12 can be employed in an inverter for ignition of a fluorescent lamp or LCD backlight.

FIG. 12(a) illustrates the method of driving the piezoelectric transformer having the uniformly-divided upper electrodes 1-8 and a monolithic lower electrode according to the third embodiment. Here, electrodes 1, 3, 5, 7 among the upper electrodes serve as the input (drive) section, electrodes 2, 4, 6, 8 serve as the output (generating) section, and the lower monolithic electrode is connected to (−) terminal.

FIG. 12(b) illustrates another method of connecting in which the same piezoelectric transformer as in FIG. 12(a). Here, the lower monolithic electrode serves as the input (drive) section, upper electrodes 2, 4, 6, 8 serve as the output section, and upper electrodes 1, 3, 5, 7 serve as (−) terminal.

In both FIGS. 12(a) and 12(b), the output section consists of four electrodes, each of which can be connected to a lamp such as CCFL (Cold Cathode Fluorescent lamp) for operating.

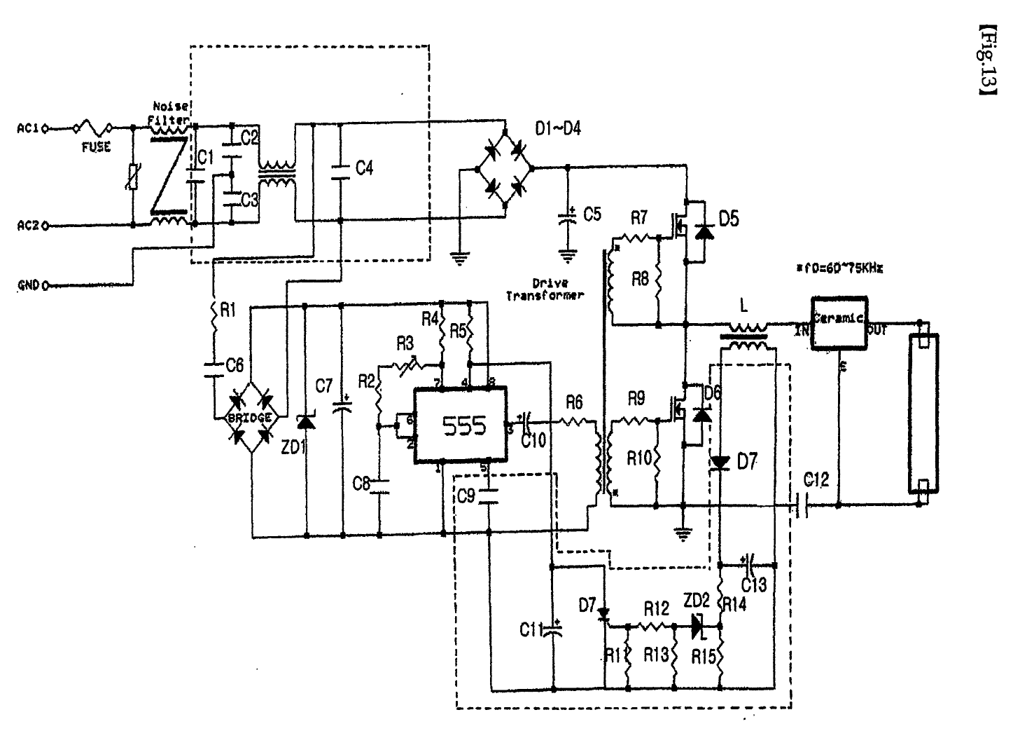

Now, an example of the drive circuit of such piezoelectric transformer is described in the following. An example of the ballast circuit for ignition of a 10-64 W discharge lamp using the piezoelectric transformer as per the present invention is illustrated in FIG. 13.

Power supplies AC1, AC2 are the commercially supplied a.c. power supply, the fuse is used for overcurrent protection, and the varistor parallel connected to the input AC line is used as overvoltage protection member. A noise filter and condensers C1, C2, C3 are used for EMI prevention, and the iron-core coil and condenser C4 are used for improving power factor, which augments the phase differences of voltage and of current to improve the power factor.

When 220V of the commercially supplied a.c. voltage is applied, the applied voltage is rectified through bridge diodes D1˜D4 and then the energy is condensed and smoothed by C4: Further, the a.c. voltage is dropped through R1 and C6, rectified through the bridge diodes, and used as the power supply for IC. In order to keep the IC voltage constant, a zener diode of 12V ZDI is used and C7 is used as smoothing condenser for IC voltage. KA555 IC is a pulse generator for output, and the switching frequency is set by R3, R2, and C8 (RT/CT). The pin number 4 of IC is a reset pin, which is pulled up by R5 and stabilized in high position by C11 at normal condition. When an anomalous current is generated, voltage is applied to D8 gate to make pin 4 go low for stopping the oscillation. The pin number 3 of IC is an output pin, which generates rectangular pulses. This output pulses are transmitted to the drive transformer through C10 and FET is driven by the drive transformer. When the drive voltage of a predetermined frequency is applied to FET gate, Q1 and Q2 alternately switch to generate the output AC from FET and further to resonate the inductor L and the piezoelectric element for lighting the lamp. In the mean time, a secondary winding is provided to inductor L so as to detect a current at overload or no-load for distribution of the voltage to R14 and R15. Further, when anomalous voltage is detected by zener diode ZD2 and applied to D8 gate, then, pin 4 is reset to stop oscillation of IC. In this way, the inverter stops switching and the ballast is safely protected.

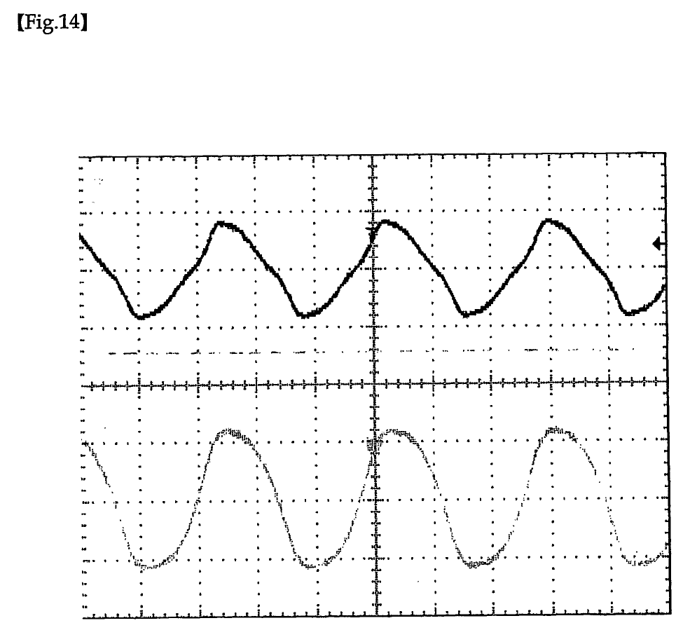

FIG. 14 illustrates the waveforms of voltage and current when a linear tubular 32-W fluorescent lamp of 25.5 mm in diameter is ignited using the drive circuit as in FIG. 13 wherein a piezoelectric transformer as in FIG. 12(a) is provided. The upper graph represents the waveform of tubular voltage and the lower graph represents the waveform of tubular current. It can be seen from the current wave that the piezoelectric ballast according to the present invention is highly efficient.

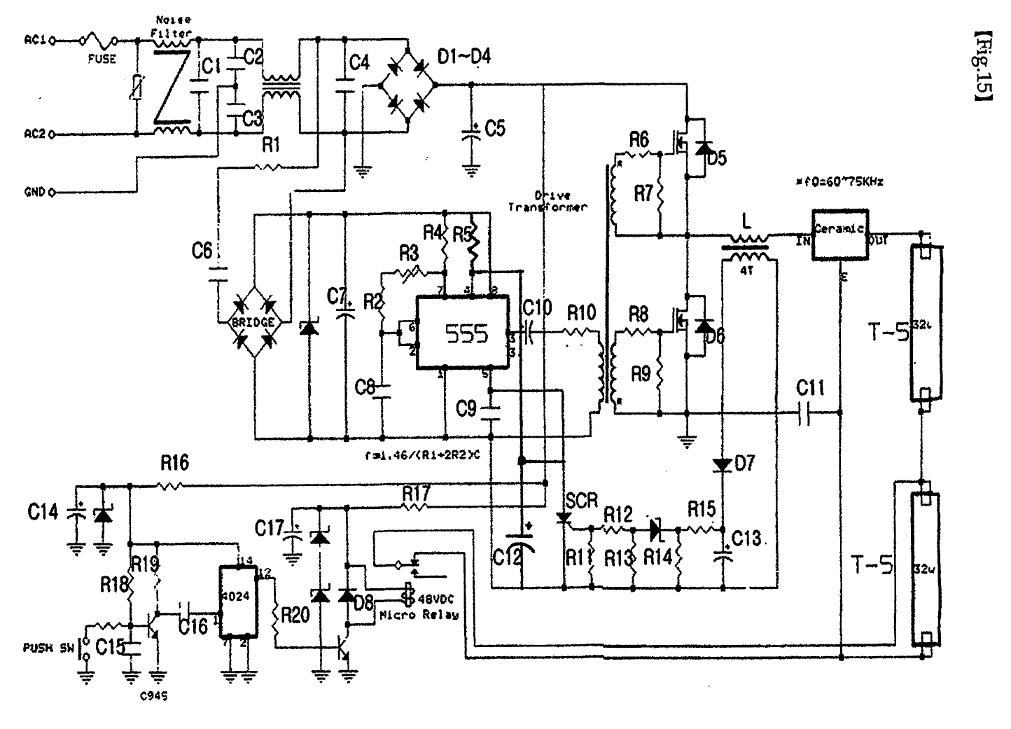

FIG. 15 illustrates a drive circuit of the piezoelectric ballast for series-connected two lamps according to the present invention. The basic constituent components of the ballast are the same as shown in FIG. 13. However a series no-load prevention circuit is added for solving the problem that the other lamp is simultaneously extinguished if one of the two series-connected fluorescent lamps is made no-load (see lower part of the circuit on the left). 4024 IC is a CMOS IC, which requires 3˜18V as binary counter. To the circuit of FIG. 15 static 12V voltage is applied by using C14, R16, and a zener diode. When the switch is open, collector Q1 is low, i.e., zero. Upon clicking the switch, the collector is changed high from low and then changed low again, whereby generating a pulse. Here, C15 is used for removal of switching noise and C16 is used for entering the pulse only. The pulse so produced enters input pin 1 of 4024 IC (binary counter) to be counted. Pin 12 is the output of the first flip-flop of the counter. When a pulse is entered, a high output is generated and then a low output is generated with the next pulse, which procedure is repeated. Such output from the counter is entered Q2 and then the relay is operated. The relay is responsible for on/off of F2 and controls both ends by short circuit and open circuit. Here, C17, R17, and two zener diodes generate a static voltage so as to operate the relay, and D8 protects the transistor against the reverse electromotive force from the relay. Accordingly, if the switch is clicked once, F2 is on, and if the switch is clicked once again, F2 is off.

In case where one of the series-connected two lamps is turned off (no-loaded), this circuit can prevent the other lamp from being extinguished by cutting off the circuit on the part of the no-loaded lamp while at the same time allowing the current to flow in the other lamp. Further, this series no-load prevention circuit can be utilized in a series bi-lamp electronic ballast as well as in a piezoelectric ballast.

Below, the results of experiments in which a lamp is substantially ignited using the piezoelectric transformer of the present invention are described.

### Experiment 1

The piezoelectric and dielectric characteristics of the ceramics piezoelectric element used in the experiments are shown in Table 2. A sine wave of 0˜220Vᵣₘₛ was used as the input voltage for drive section and the input frequency of 3λ/2 mode at which maximum output was obtained was used.

TABLE 2
Piezoelectric and Dielectric Characteristics of the Ceramics
Piezoelectric Element Used in the Experiments

| General Formula | Pb(Mn_{1/3}Nb_{2/3}) − PZT + additive |
|---|---|
| Planar Electric Mechanical | 0.55-0.62 |
| Combination Coefficient (Kₚ) | |
| Dielectric Constant | 500-1200 |
| Tanδ (%) | 0.1-0.3 |
| Qm | 1500-2200 |
| Tc | ≈310° C. |

The circuit configuration of the disc-type four-division piezoelectric transformer used in the present experiment is the same as in FIG. 9. The spacing between electrodes is 1 mm, the diameter of the disc is 34.7 mm, and the thickness of the disc is 3 mm. The input voltage for a 24-W fluorescent lamp was 220Vᵣₘₛ of the commercially supplied power line and the power efficiency (output power/input power) measured after lighting the lamp by applying 73.1 kHz of oscillation frequency was over 93%.

### Experiment 2

The lower surface of the ceramics used in Experiment 1 was divided in the same manner as the upper surface and the spacing between electrodes was rendered 1 mm. The ceramics was 2 mm in thickness and 34.7 mm in diameter. The circuit configuration of the piezoelectric transformer was the same as in FIG. 10. Electrodes 1, 2 and 3, 4 from the drive section were connected in series and electrodes 1′, 2′ and 3′, 4′ were connected in parallel.

Meanwhile, a 27-W CFL (Compact Fluorescent Lamp) was supplied with the input power of 29 W and the input frequency of 73.1 kHz for ignition and then the measured power efficiency (output power/input power) was over 90%.

### Experiment 3

After a disc type element having a diameter of 44 mm and a thickness of 2.5 mm with ten divisional electrodes was connected with the input and output terminals in the same manner as in FIG. 12(b), a linear tubular 28 W fluorescent lamp (T5) having a diameter of 15.5 mm and the drive circuit as in FIG. 13 were connected for applying the input power of 27 Watt (input current: 0.15A, input voltage: 220V) and the input frequency of 44.5 kHz. The results in electrical characteristics of the piezoelectric ballast were as shown in Table 3 and the power efficiency was over 93%. Here, the tubular current was 0.134A, which is more than 10 times as large as the output current of the conventional common piezoelectric transformer. Further, whereas the calorific temperature of a fluorescent lamp is 65˜70° C. when the lamp is ignited using a conventional electronic ballast, the calorific temperature by the piezoelectric ballast is 40˜45° C., which is remarkable. Such temperature characteristic can be said to be a general typical characteristic of the piezoelectric ballast pursuant to the present invention.

In the meantime, the results attained by connecting respectively 14-, 21-, 28-, and 35-Watt T5 fluorescent lamps to a single piezoelectric ballast are shown in Table 3. As can be seen in Table 3, regardless of power dissipation of the lamps, the input power dissipation of the piezoelectric ballast according to the present invention is regulated in an automatic manner, which assures that unlike in the conventional electronic ballast, the circuits can be operated as common circuits in the piezoelectric ballast.

The overload circuit illustrated in FIG. 13 has the feature of a no-load circuit, as well. A pre-heated ignition circuit and a soft start circuit are excluded from the constituent circuits for the characteristics of the present element. If not mentioned otherwise, the circuit as in FIG. 13 is used for the in-lamp circuit using the present element. Here, the efficiency means output power/input power.

TABLE 3
Electrical characteristics of the piezoelectric ballast for
T5 lamp according to the present invention

| | Input Power | Power | Tubular | Tubular | Efficiency |
|---|---|---|---|---|---|
| Lamp | (W) | Factor (%) | Current (A) | Voltage (V) | (%) |
| 14 W | 13.2 | 98 | 0.123 | 105 | 95.9 |
| 21 W | 20.1 | 98 | 0.129 | 151 | 95.0 |
| 28 W | 27.0 | 98 | 0.134 | 192 | 93.4 |
| 35 W | 33.8 | 98 | 0.132 | 241 | 92.2 |

### Experiment 4

The piezoelectric transformer of 44 mm in diameter and 2.5 mm in thickness with ten divisional electrodes was connected as in FIG. 12(b) for connection with a 32 W linear tubular fluorescent lamp (T8) of 25.5 mm in diameter and the drive circuit as in FIG. 13, with the results as shown in Table 4.

TABLE 4
Electrical characteristics of the piezoelectric ballast
for 32 W T8 lamp according to the present invention

| | | Power | | | |
|---|---|---|---|---|---|
| | Input | factor | Tubular | Tubular | Efficiency |
| Lamp | Power (W) | (%) | Current (A) | Voltage (V) | (%) |
| 32 W | 30 | 98 | 0.193 | 148 | 93.3 |

### Experiment 5

The piezoelectric transformer of 50 mm in diameter and 2.0 mm in thickness with ten divisional electrodes was connected as in FIG. 12(b) for connection with a 55 W U-shaped PLL lamp and the drive circuit as in FIG. 13, with the results as shown in Table 5. In the case of PLL lamp, too, the lamp could be ignited by a single common ballast, regardless of power dissipation of the lamp.

TABLE 5
Electrical characteristics of the piezoelectric ballast
for 55 W PLL lamp according to the present invention

| | Input | Power | | | |
|---|---|---|---|---|---|
| | Power | factor | Tubular | Tubular | Efficiency |
| Lamp | (W) | (%) | Current (A) | Voltage (V) | (%) |
| 55 W | 50 | 98 | 0.41 | 112 | 90.0 |

### Experiment 6

On the upper surface of the disc-type element of 50 mm in diameter and 3.5 mm in thickness was connected a piezoelectric transformer in an alternate manner as in FIG. 12(a). Then, 51.5 watt of input power and 81.2 kHz of input frequency were applied for series connection of two T5 fluorescent lamps of 28 W. The electrical characteristics are as shown in Table 6. The series-connected two lamps were ignited to provide equal illumination, which was the same illumination as that provided when a single of the present element was supplied with 26 W of input power and 79.4 kHz of input frequency for ignition of a 28 W T5 lamp.

TABLE 6
Electrical characteristics of the piezoelectric
ballast for series-connected two 28 W T5 lamps
according to the present invention

| | Input | Power | | | |
|---|---|---|---|---|---|
| | Power | factor | Tubular | Tubular | Efficiency |
| Lamp | (W) | (%) | Current (A) | Voltage (V) | (%) |
| 28 W T5 two | 51.5 | 98 | 0.133 | 378 | 95.7 |
| lamps | | | | | |

Table 7 shows the maximum output values according to the size of the piezoelectric element, which are results obtained from experiments of ignition of a variety of fluorescent lamps using the piezoelectric ballast according to the present invention. Table 7 also lists applicable lamps based on these maximum output values.

TABLE 7
Applicable lamps according to the size of the piezoelectric
transformer

| Size of | | Maximum | Maximum | | |
|---|---|---|---|---|---|
| Piezoelectric | | Output | Output | Resonant | Applicable |
| Element | | Power | Current | Frequency | Lamps |
| φ 34 | mm | 28 W | 120 mA | About 90 kHz | T5 14 W, 21 W, |
| 2.5 | mm | | | | 28 W |
| φ 40 | mm | 36 W | 200 mA | About 85 kHz | T5 32 W, 35 W, |
| 2.5 | mm | | | | T8 32 W, PLL |
| | | | | 36 W | |
| φ 44 | mm | 56 W | 300 mA | About 75 kHz | T8 32 W series- |
| 2.5 | mm | | | | connected two |
| | | | | lamps | |
| φ 50 | mm | 75 W | 500 mA | About 65 kHz | T5 28 W, 32 W |
| 2.5 | mm | | | | series-connected |
| | | | | two lamps | |

### Experiment 7

The piezoelectric ceramic of 13 mm in diameter and 3.0 mm in thickness was used with divisional electrodes as in FIG. 9 and two divisional electrodes 1, 3 among the total four served as the input section and the other two electrodes 2, 4 served as the output section for parallel connection of two CCFLs of 2.6 mm in diameter and 460 mm in length. As a result, both CCFLs normally operated and were maintained when an input voltage of 50Vᵣₘₛ was applied thereto. The electrical characteristics are given in Table 8. These characteristics can allow great reduction of the size of the inverter in comparison to the piezoelectric inverter using the conventional Rosen type piezoelectric transformer. These characteristics further imply that the piezoelectric transformer can serve as the inverter for large LCD backlight.

TABLE 8
Electrical characteristics in case of lighting
a CCFL of 46 mm in diameter using the piezoelectric
transformer according to the present invention

| Drive | Drive | Starting | Maintenance | Tubular | Illumi- | Effi- |
|---|---|---|---|---|---|---|
| Frequency | Voltage | Voltage | Voltage | Current | nation | ciency |
| (kHz) | (Vᵣₘₛ) | (Vᵣₘₛ) | (Vᵣₘₛ) | (mA) | (cd/m²) | (%) |
| 207 | 50 | ˜2000 | ˜1000 | ˜10 | 35,000 | 90 |

The present invention can provide output of high voltage and of high current by 6 means of a piezoelectric transformer having a novel configuration of the electrodes and a novel arrangement of the poling direction. Further, with various methods for connection of the electrodes, multiple outputs as many as the number of divisional electrodes of the output section can be obtained from a single piezoelectric transformer. Still further, durability and mass-productivity can be secured due to the isotropic poling direction of the drive (input) section and the output section, with the result of capability of lighting a general fluorescent lamp for home use at the commercially supplied power lines, which is impossible with the conventional transformer. In case of application to the inverter for LCD backlight with the method of multiple outputs, not only can the inverter be reduced in size but also a plurality of CCFLs can simultaneously be ignited using a single inverter.

What is claimed is:

1. A piezoelectric transformer comprising a planar disc-type or ring-type body made of piezoelectric material; and the first and the second electrodes, both of which having the same planar structure as the body and being divided into N divisions with predetermined spacing therebetween in a manner that the arrangement of the first and the second electrodes is symmetrical with respect to the plane of the body, which are formed adjacent to the upper and the lower surfaces of the body, respectively, wherein
said body is polarized throughout in an equal field direction, and
N1 divisions of the first electrode (N1=positive integer, N1<N) are supplied with the input voltage, the second electrode is supplied with common negative potential, and the output voltage is taken from the other N-N1 divisions of the first electrode.

2. A piezoelectric transformer comprising a planar disc-type or ring-type body made of piezoelectric material; the first electrode, having the same planar structure as the body and being divided into N divisions with predetermined spacing therebetween, which is formed adjacent to one of the upper and the lower surfaces of the body; and the second electrode, having the same planar structure as the body, which is monolithical formed adjacent to the surface opposite to the surface formed adjacent to the electrode, wherein
the body is polarized throughout in an equal field direction, and
N1 divisions of the first electrode (N1=positive interger,N1<N) are supplied with the input voltage, the second electrode is supplied with negative potenial; and the output voltage is taken from the other N-N1 divisions of the first electrode.

3. A piezoelectric transformer comprising a planar disc-type or ring-type body made of piezoelectric material; the first electrode, having the same planar structure as the body and being divided into N divisions with predetermined spacing therebetween, which is formed adjacent to one of the upper and the lower surfaces of the body; and the second electrode, having the same planar structure as the body, which is monolithically formed adjacent to the surface opposite to the surface formed adjacent to the first electrode, wherein
the body is polarized throughout in an equal field direction, and
the second electrode is supplied with the input voltage, N1 divisions of the first electrode (N1=positive integer, N1<N) are supplied with the common negative potential, and the output voltage is taken from the other N-N1 divisions of the first electrode.

4. The piezoelectric transformer as set forth in any one of claims 1 through 3, wherein said body is polarized in the axial direction.

5. The piezoelectric transformer as set forth in any one of claims 1 through 3, wherein said first electrode is formed by dividing the central angle of 360° of said disc-type or ring-type body into N uniform divisions in a radial manner.

6. The piezoelectric transformer as set forth in any one of claims 1 and 2, wherein said N1 divisional electrodes to which the input voltage is applied are connected in parallel, in series, or in combination of parallel and series.

7. The piezoelectric transformer as set forth in claim 6, wherein said connected N1 divisional electrodes are physically adjacent to each other.

8. The piezoelectric transformer as set forth in claim 6, wherein said connected N1 divisional electrodes are arranged in an alternate manner with the other N-N1 divisional electrodes to which the input voltage is not applied.

9. The piezoelectric transformer as set forth in any one of claims 1 through 3, wherein said N-N1 divisional electrodes from which the output voltage is taken are each independently connected to no more than N-N1 loads in parallel to provide no more than N-N1 outputs.

10. A piezoelectric ballast for fluorescent lamp which comprises:
an a.c. power supply including an overcurrent protection member, an overvoltage protection member and an EMI prevention circuit;
a power factor improving circuit connected to said a.c. power supply;
a rectifier connected to said power factor improving circuit;
a pulse generator receiving the input voltage from said a.c. power supply;
a switching frequency setting circuit for setting switching frequency of said pulse generator;
a resonant circuit comprising a drive transformer that transforms the output from said pulse generator, two field-effect transistors that are connected to said drive transformer for switching the output a.c. voltage from said rectifier, an inductor connected to said two field-effect transistors, a piezoelectric transformer connected to said inductor in series, and a fluorescent lamp; and
a reset circuit which is connected to said pulse generator for resetting said pulse generator in the event of overload or no-load,
said piezoelectric transformer having the same configuration as described in any one of claims 1 through 3.

11. The piezoelectric ballast for fluorescent lamp as set forth in claim 10, wherein said reset circuit comprises a secondary winding that is formed facing said inductor for detecting anomalous current in the fluorescent lamp at overload or no-load; a zener diode connected to said secondary winding for detecting anomalous voltage; and a SCR (Silicon-Controlled Rectifier) that is operated by a signal from said zener diode.

12. A piezoelectric ballast for fluorescent lamp which comprises:
an a.c. power supply including an overcurrent protection member, an overvoltage protection member and an EMI prevention circuit;
a power factor improving circuit connected to said a.c. power supply;
a rectifier connected to said power factor improving circuit;
a pulse generator receiving the input voltage from said a.c. power supply;
a switching frequency setting circuit for setting switching frequency of said pulse generator;
a resonant circuit comprising a drive transformer that transforms the output from said pulse generator, two field-effect transistors that are connected to said drive transformer for switching the output a.c. voltage from said rectifier, an inductor connected to said two field-effect transistors, a piezoelectric transformer connected to said inductor in series, and at least two series-connected fluorescent lamps;
a reset circuit which is connected to said pulse generator for resetting said pulse generator in the event of overload or no-load; and
a series no-load circuit which, connected to each of said series-connected fluorescent lamps, if one of the lamps is turned off with no-load, allows the current to flow only in the other lamp while at the same time cutting off the circuit for the extinguished lamp.

13. The piezoelectric ballast for fluorescent lamp as set forth in claim 12, wherein said piezoelectric transformer has the same configuration as described in any one of claims 1 through 3.
